(19) United States
(12) Patent Application Publication
(10) Pub. No.: US 2026/0025937 A1
(43) Pub. Date: Jan. 22, 2026

(54) Server Information Handling System Peripheral Riser Module System

(71) Applicant: Dell Products L.P., Round Rock, TX (US)

(72) Inventors: Pei-Chuan Hsieh, Xizhi Dist. (TW); Kuang-Hsi Lin, Bade Dist. (TW); Po Li Hsieh, Taoyuan (TW)

(21) Appl. No.: 18/773,658

(22) Filed: Jul. 16, 2024

(51) Int. Cl. H05K 7/14

(52) U.S. Cl. CPC H05K 7/1489; H05K 7/1401; H05K 7/1492

(57) ABSTRACT

A peripheral mounting system. The peripheral mounting system includes a riser tray housing; and, a latch component, the latch component including a latch main housing portion; a pin engagement feature physically coupled to the latch main housing portion; and, a travel control feature physically coupled to the latch main housing, the travel control feature allowing the latch component to move in the peripheral mounting system between a locked position and an unlocked position.

### BACKGROUND OF THE INVENTION

### FIELD OF THE INVENTION

The present invention relates to information handling systems. More specifically, embodiments of the invention relate to server type information handling systems within information technology (IT) environments.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a sliding peripheral mounting system.

In one embodiment, the invention relates to a latch component of a peripheral mounting system for use with an information handling system, comprising: a latch main housing portion; a pin engagement feature physically coupled to the latch main housing portion; and, a travel control feature physically coupled to the latch main housing, the travel control feature allowing the latch component to move in the peripheral mounting system between a locked position and an unlocked position.

In another embodiment, the invention relates to peripheral tray system comprising: a chassis; and, a peripheral mounting system mounted to the chassis, the peripheral mounting system comprising a latch main housing portion; a pin engagement feature physically coupled to the latch main housing portion; and, a travel control feature physically coupled to the latch main housing, the travel control feature allowing the latch component to move in the peripheral mounting system between a locked position and an unlocked position.

In another embodiment, the invention relates to a system comprising: a chassis; a processor contained within the chassis; a data bus coupled to the processor; and, a peripheral mounting system comprising a latch main housing portion; a pin engagement feature physically coupled to the latch main housing portion; and, a travel control feature physically coupled to the latch main housing, the travel control feature allowing the latch component to move in the peripheral mounting system between a locked position and an unlocked position.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a perspective view of a riser cage mounted within an information handling system.

FIGS. 5A and 5B, generally referred to as FIG. 5, show a portion of a riser cage in a plurality of mounting configurations.

FIG. 6A and 6B, generally referred to as FIG. 6, show cut away section views of a latch component within a portion of a riser cage.

FIGS. 7A, 7B, 7C, 7D, 7E, 7F, 7G and 7H, generally referred to as FIG. 7, show a plurality of views of a latch component for a riser cage.

### DETAILED DESCRIPTION

Various aspects of the disclosure include an appreciation that it is known to provide information handling systems with devices which conform to various standard specifications. Various aspects of the disclosure include an appreciation that these standard specifications include an open compute project (OCP) foundation specification and a Peripheral Component Interconnect express (PCIe) specification. Various aspects of the present disclosure include an appreciation that it is known to mount these devices within riser cages (also referred to as device bays). Various aspects of the disclosure include an appreciation that it can be desirable to install and remove the riser cages within the information handling system.

Various aspects of the present disclosure include an appreciation that certain known riser cages include a latch which is used to mount the riser cage within the information handling system. Various aspects of the present disclosure include an appreciation that with certain known riser cages the latch can often make it difficult to remove the riser cage from the information handling system. Various aspects of the present disclosure include an appreciation that with certain known riser cages the latch can often catch on other information handling system components during the riser cage installation and removal process. Accordingly, various aspects of the disclosure include an appreciation that it would be desirable to provide a riser cage with a latch which facilitates sliding installation and removal of the riser cage.

A system and method for providing a server system with a sliding peripheral mounting system. In certain embodiments, the server information handling system includes an information handling system chassis which includes a sliding peripheral mounting system. In certain embodiments, the sliding peripheral mounting system includes a riser cage. In certain embodiments, the riser cage includes a latch component which facilitates sliding installation and removal of the riser cage. In certain embodiments, the latch component is configured to perform a sliding installation function, a sliding removal function, or a combination thereof. In certain embodiments, the riser cage is configured to be mounted within a 1U type server system, a 2U type server system, or a combination thereof. In certain embodiments, the riser cage is configured to be mounted to a high performance module (HPM) of the server system.

In certain embodiments, the latch component includes a pin engagement feature. In certain embodiments, the pin engagement feature interacts with the HPM. In certain embodiments, the pin engagement feature interacts with a guide pin which is mounted to the HPM. In certain embodiments, when the latch component is slid in one direction (e.g., towards the rear of the riser bay), the pin engagement feature engages the guide pin. In certain embodiments, when the latch component is slid in another direction (e.g., towards the front of the riser bay) the pin engagement feature disengages the guide pin.

In certain embodiments, the latch component includes a travel control feature. In certain embodiments, the travel control feature includes a travel channel, a position fixing projection, an elastic arm, or a combination thereof. In certain embodiments, one or more fasteners attached the latch component to the riser bay. In certain embodiments, the one or more fasteners are mounted within the travel channel. In certain embodiments, the latch component includes a gripping portion. In certain embodiments, the gripping portion facilitates sliding of the latch component by a user.

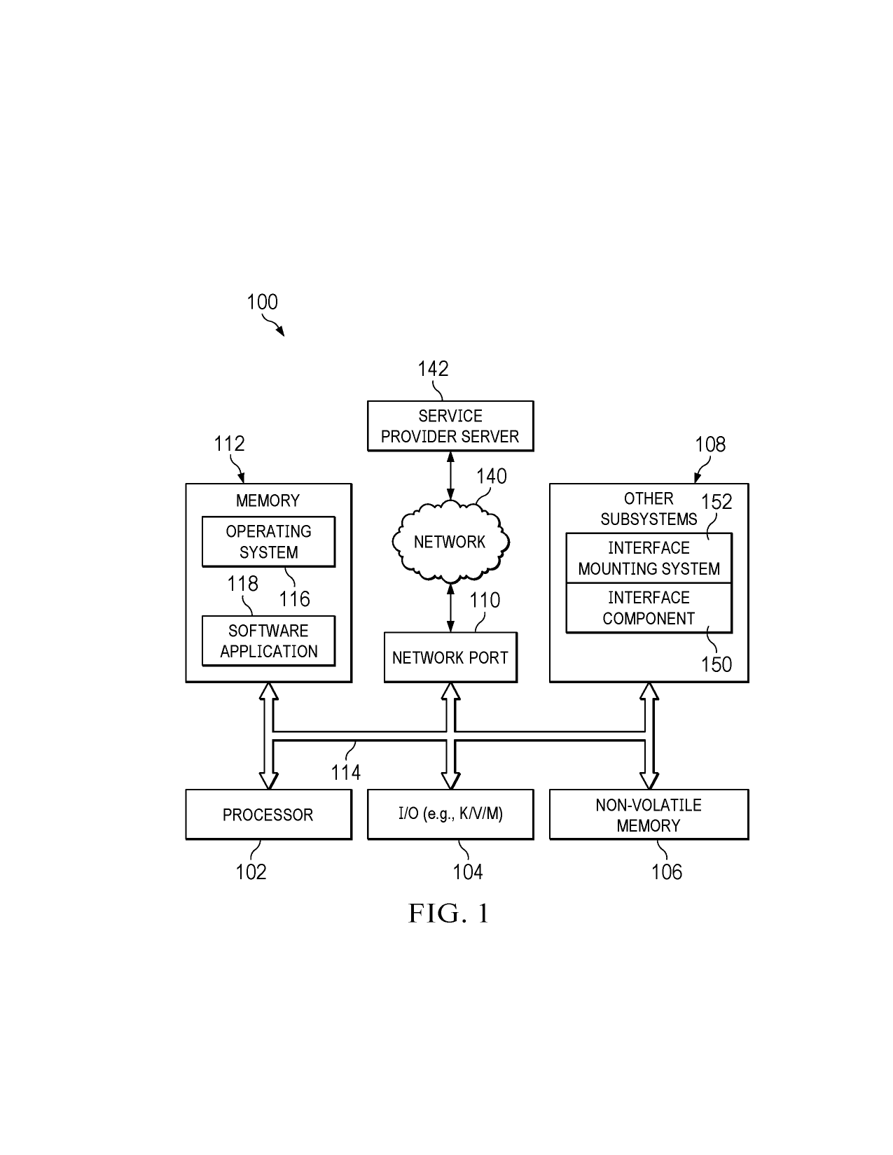

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a peripheral component 150, a peripheral component mounting system 152, or a combination thereof. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the peripheral component mounting system 152 includes a riser cage. In certain embodiments, the riser cage includes a latch component which facilitates sliding installation and removal of the riser cage. In certain embodiments, the latch component is configured to perform a sliding installation function, a sliding removal function, or a combination thereof. In certain embodiments, the riser cage is configured to be mounted within a 1U type server system, a 2U type server system, or a combination thereof. In certain embodiments, the riser cage is configured to be mounted to a high performance module (HPM) of the server system.

In certain embodiments, the latch component includes a pin engagement feature. In certain embodiments, the pin engagement feature interacts with the HPM. In certain embodiments, the pin engagement feature interacts with a guide pin which is mounted to the HPM. In certain embodiments, when the latch component is slid in one direction (e.g., towards the rear of the riser bay), the pin engagement feature engages the guide pin. In certain embodiments, when the latch component is slid in another direction (e.g., towards the front of the riser bay)the pin engagement feature disengages the guide pin.

In certain embodiments, the latch component includes a travel control feature. In certain embodiments, the travel control feature includes a travel channel, a position fixing projection, an elastic arm, or a combination thereof. In certain embodiments, one or more fasteners attached the latch component to the riser bay. In certain embodiments, the one or more fasteners are mounted within the travel channel. In certain embodiments, the latch component includes a gripping portion. In certain embodiments, the gripping portion facilitates sliding of the latch component by a user.

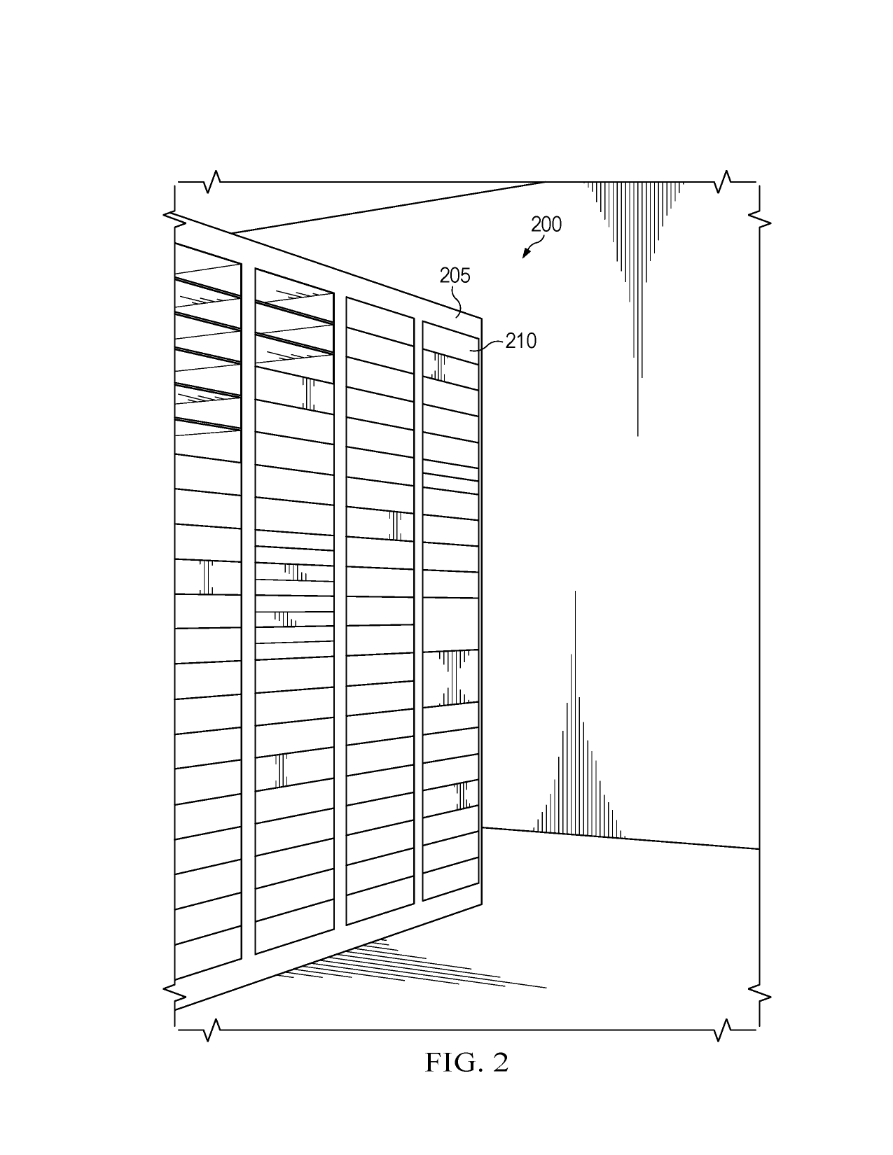

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuously with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/-20%) 1.75” high, a 2U rack unit is substantially (i.e., +/-20%) 3.5” high and a 4U rack height is substantially (i.e., +/-20%) 7.0” high.

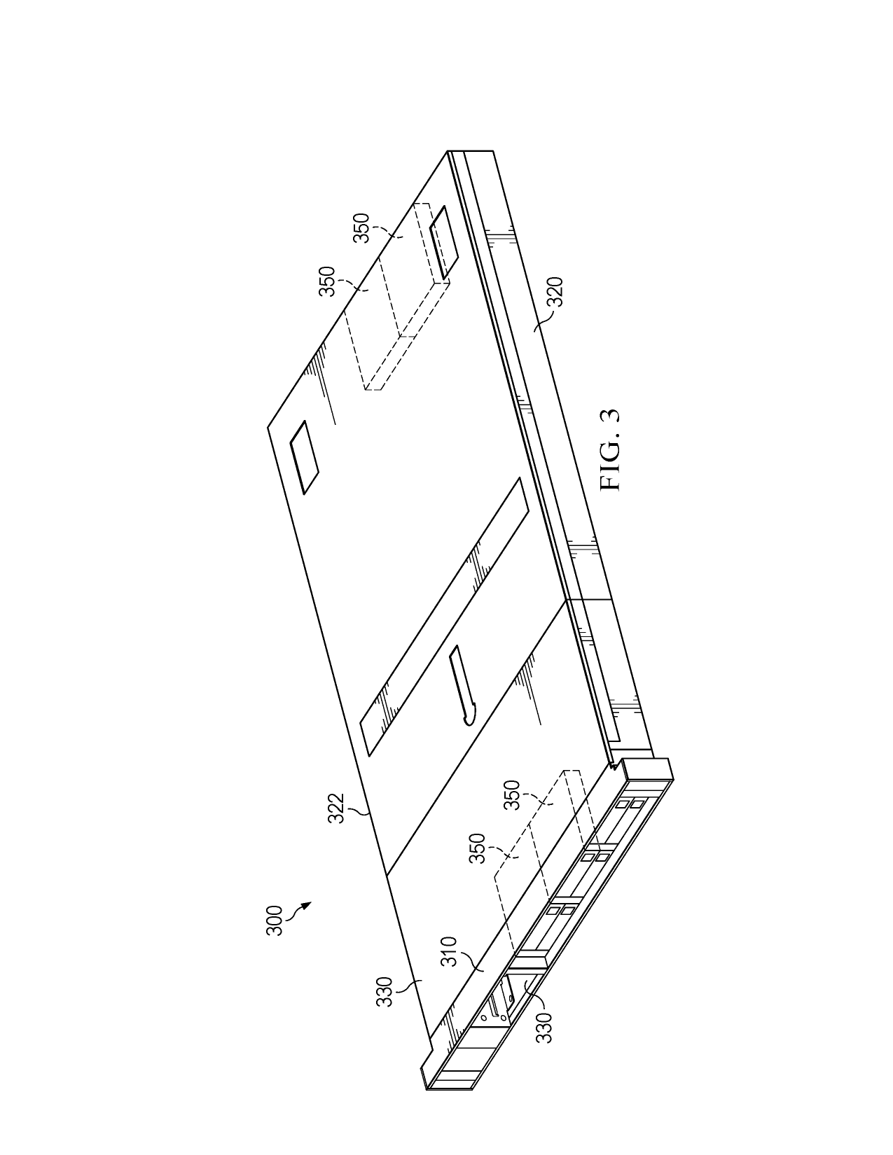

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes one or more bays 350 via which components may be mounted to the blade type information handling system. In certain embodiments, one or more bays 350 include a peripheral component mounting system such as the peripheral component mounting system 152 includes a riser cage.

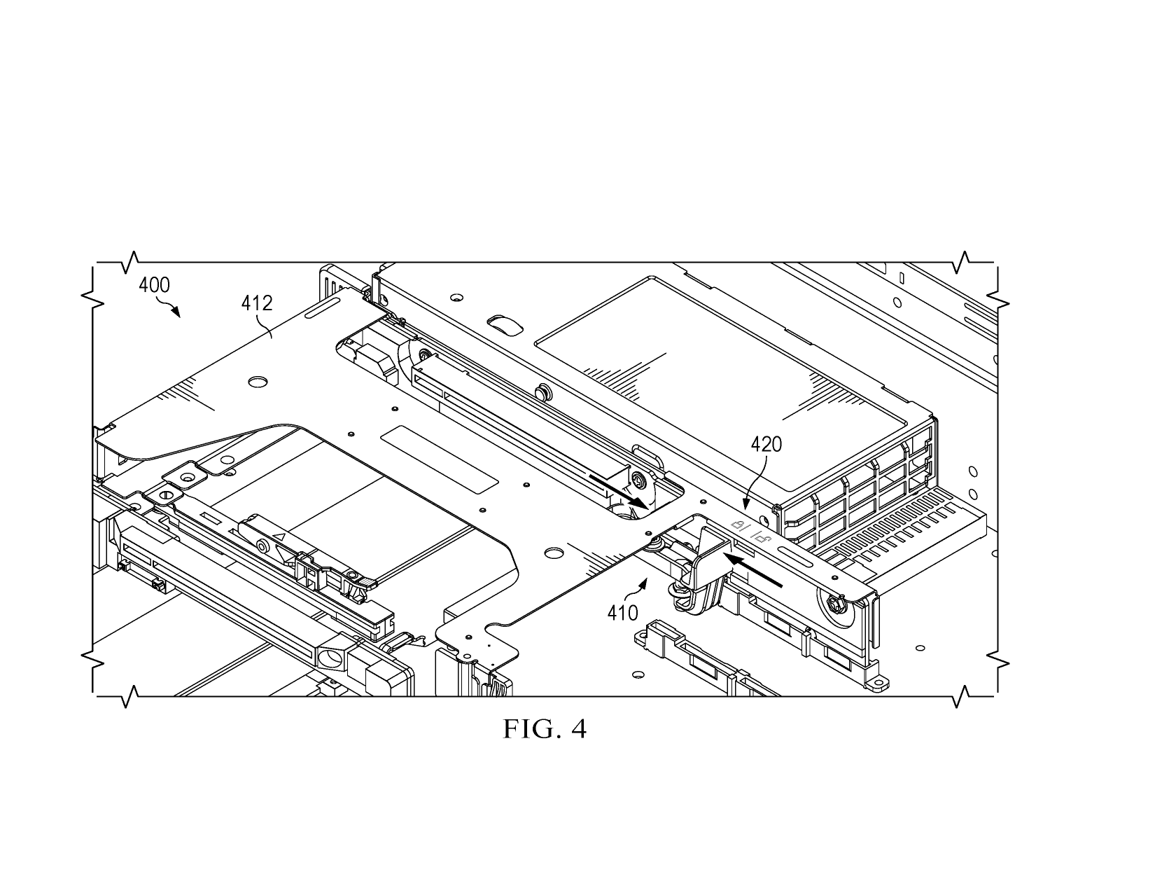

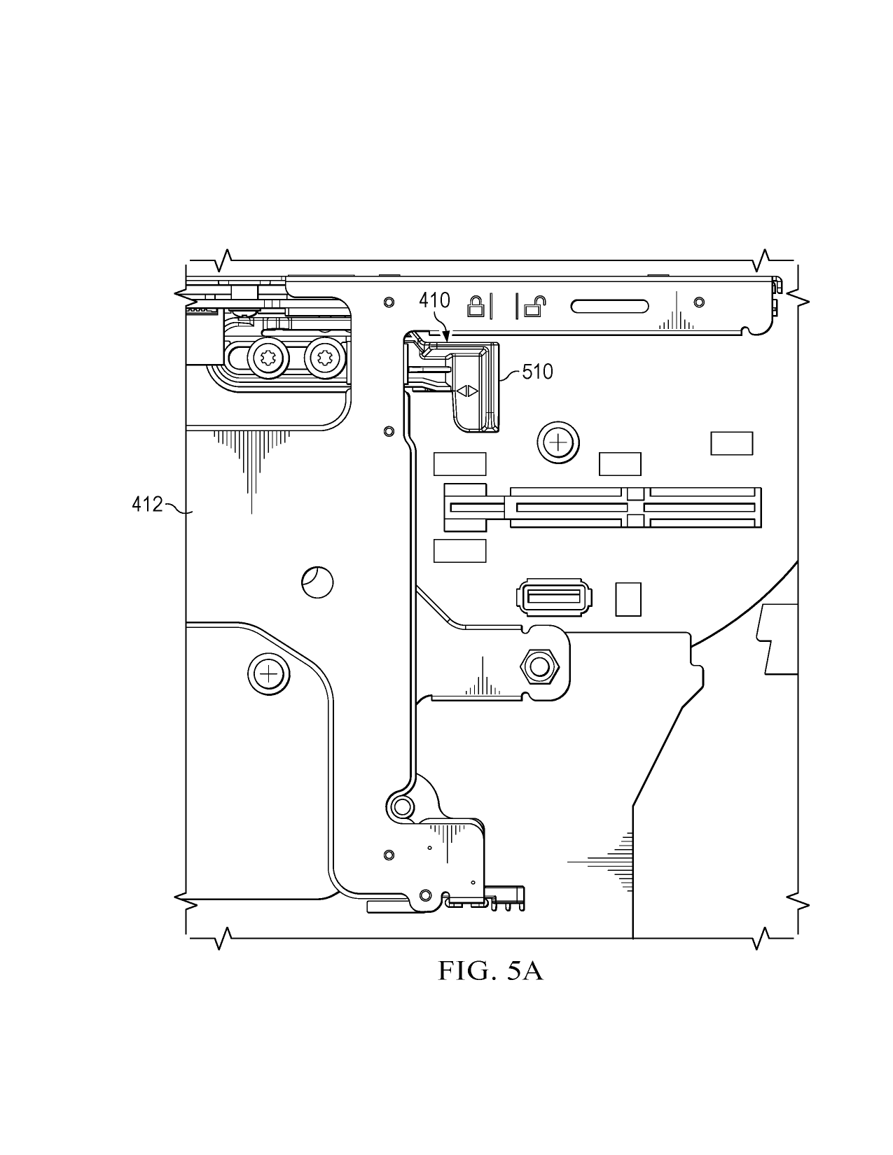

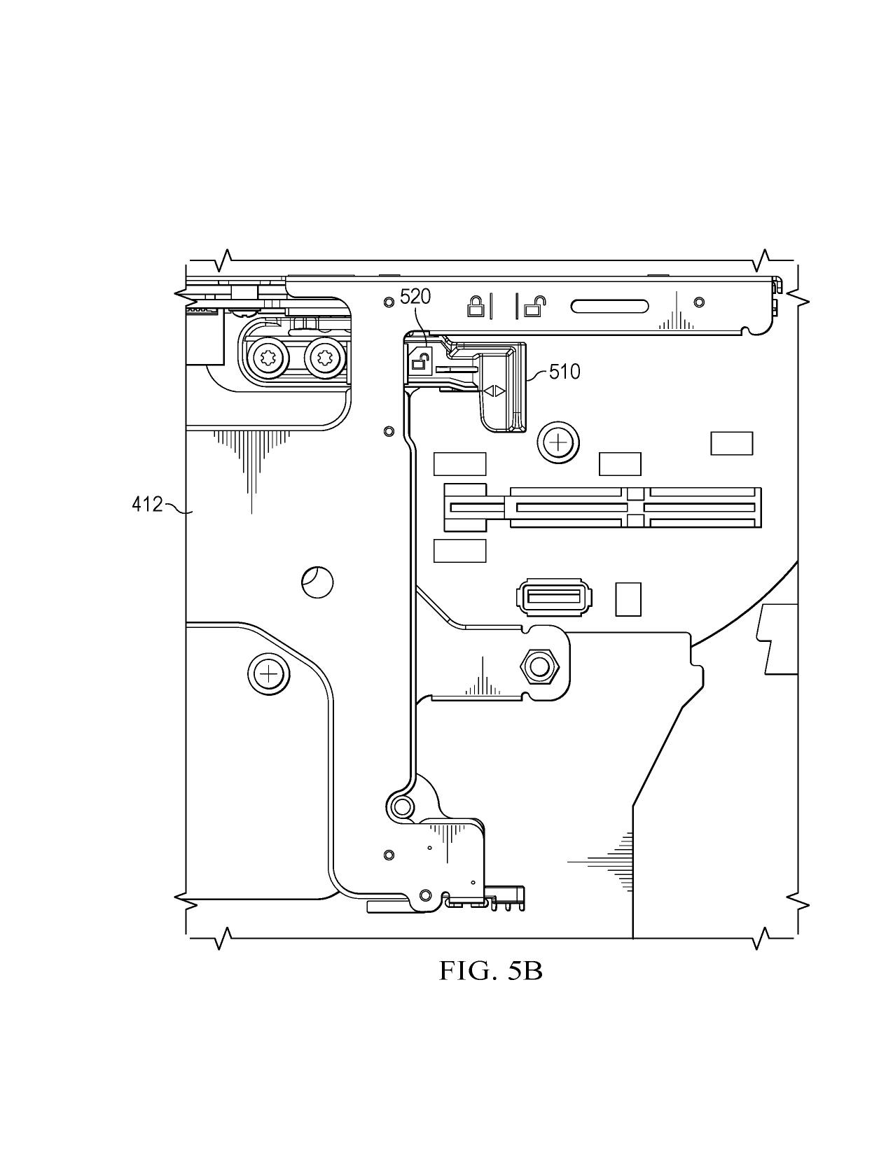

FIG. 4 shows a perspective view of a riser cage 400 mounted within an information handling system. FIGS. 5A and 5B, generally referred to as FIG. 5, show a portion of a riser cage in a plurality of mounting configurations. In certain embodiments, the riser cage 400 corresponds to peripheral component mounting system 152.

In certain embodiments, the riser cage 400 includes a latch component 410, a riser cage housing 412, or a combination thereof. In certain embodiments, the latch component 410 slides to facilitate installation and removal of the riser cage 400. In certain embodiments, the latch component 410 is configured to perform a sliding installation function, a sliding removal function, or a combination thereof. In certain embodiments, the riser cage 400 is configured to be mounted within a 1U type server system, a 2U type server system, or a combination thereof. In certain embodiments, the riser cage 400 is configured to be mounted to a high performance module (HPM) of the server system.

In certain embodiments, the riser cage 400 includes a riser cage installation status indicia 420. In certain embodiments, the riser cage installation status indicia 420 provides an indication of whether the riser cage is in a locked configuration or an unlocked configuration. In certain embodiments, the indication of whether the riser cage is in a locked configuration or an unlocked configuration is based upon a position of the latch component 410.

In certain embodiments, the indication of whether the riser cage is in a locked configuration or an unlocked configuration is based upon a position of a gripping portion 510 of the latch component 410. In certain embodiments, when the latch component 410 is in an unlocked configuration, the latch component 410 presents an unlocked indicia 520.

In certain embodiments, when the riser cage 400 is in an unlocked configuration, the riser cage 400 may be easily uninstalled from the information handling system. In certain embodiments, when the riser cage is in an unlocked configuration, the riser cage 400 may be easily uninstalled from the information handling system even when the riser cage 400 is installed within a limited space on the information handling system.

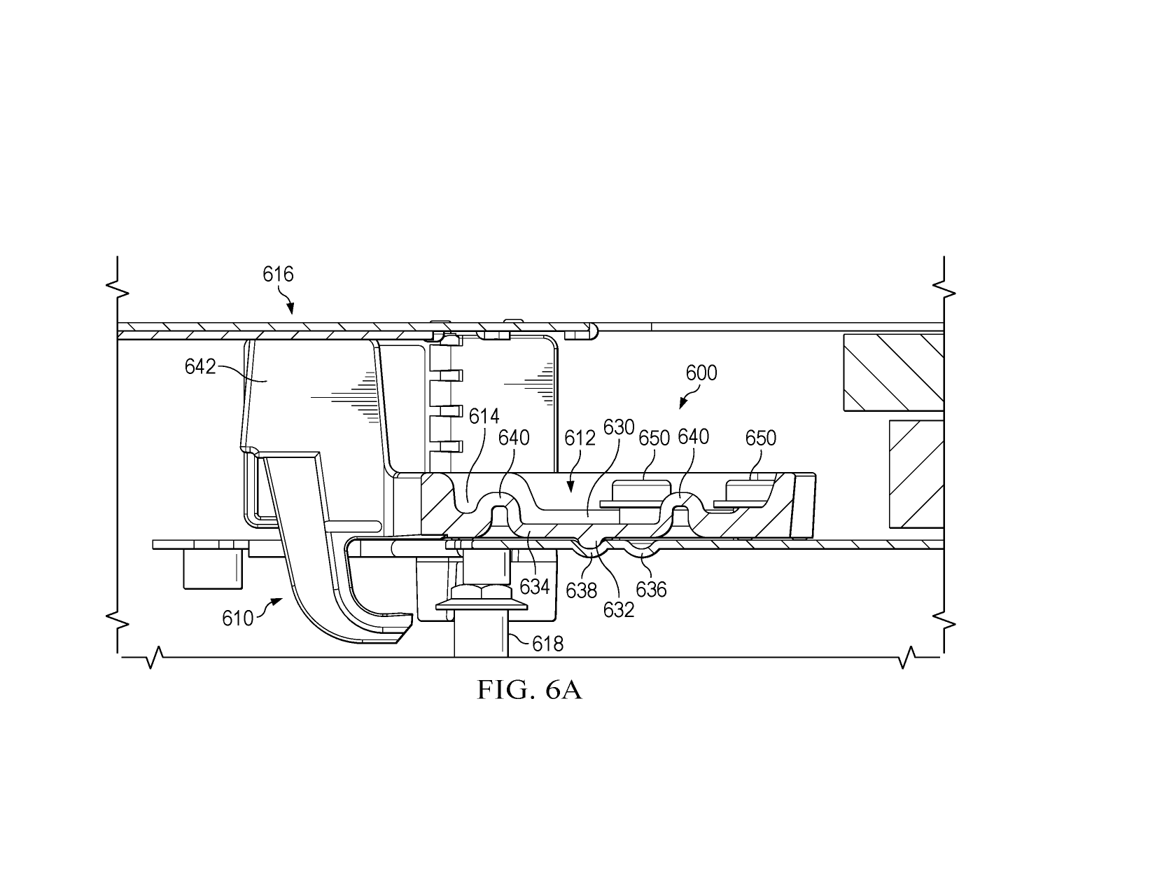

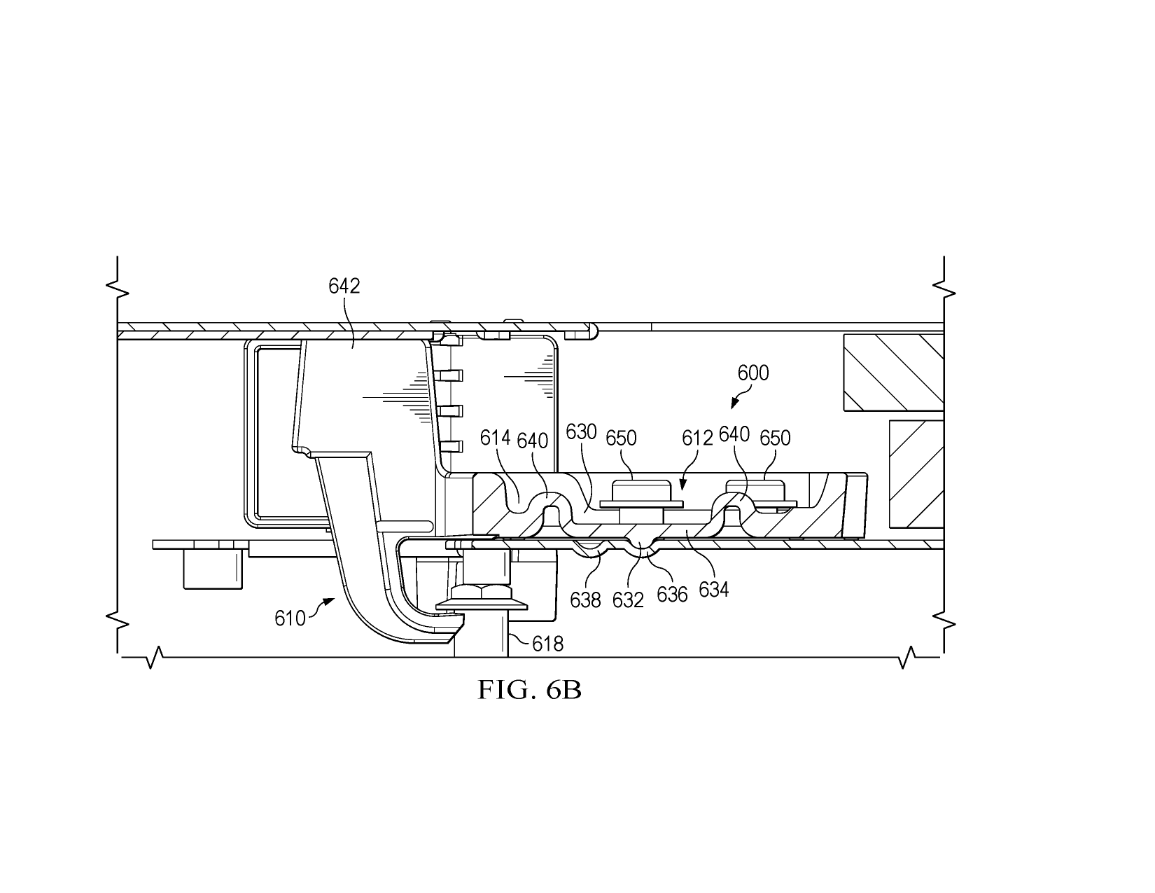

aA and 6B, generally referred to as FIG. 6, show cut away section views of a latch component 600 within a portion of a riser cage. More specifically, FIG. 6A shows a cut away section view of a latch component 600 in an unlocked configuration. FIG. 6B shows a cut away section view of a latch component in a locked configuration. In certain embodiments, the latch component 600 corresponds to latch component 410.

In certain embodiments, the latch component 600 includes a pin engagement feature 610, a travel control feature 612, a latch main housing portion 614, a handle feature 616, or a combination thereof. In certain embodiments, the pin engagement feature 610, the travel control feature 612, the handle feature 616, or a combination thereof, are physically coupled to the latch main housing portion. In certain embodiments, the pin engagement feature 610, the travel control feature 612, the latch main housing portion 614 and the handle feature 616 are constructed from a single piece of material. In certain embodiments, the pin engagement feature 610, the travel control feature 612, the latch main housing portion 614 and the handle feature 616 are constructed from plastic. In certain embodiments, the latch component 600 is constructed from a material having a color which is different from the color of the riser cage. In certain embodiments, by constructing the latch component 600 from a material having a color which is different from the color of the riser cage, the latch component 600 visually stands out when from the riser cage housing to which the latch component 600 is attached.

In certain embodiments, the pin engagement feature 610 interacts with the HPM. In certain embodiments, the pin engagement feature 610 interacts with a guide pin 618 which is mounted to the HPM. In certain embodiments, when the latch component 600 is slid in one direction (e.g., towards the rear of the riser bay), the pin engagement feature 610 engages the guide pin 618. In certain embodiments, when the latch component 600 is slid in another direction (e.g., towards the front of the riser bay) the pin engagement feature 610 disengages the guide pin 618.

In certain embodiments, the travel control feature 620 includes a travel channel 630, a position fixing projection 632, an elastic arm 634, or a combination thereof. In certain embodiments, the travel channel 630 is shaped as an elongated oval with substantially straight inside edges. In certain embodiments, the position fixing projection 630 projects downwardly from the elastic arm 634. In certain embodiments, the position fixing projection 632 mates with a lock recess 636 or an unlocked recess 638 to hold the latch component in the locked configuration or the unlocked configuration. In certain embodiments, the elastic arm 634 includes one or more spring portions 640. In certain embodiments, the one or more spring portions 640 allow the elastic arm 634 to deflect when moving between a locked configuration and an unlocked configuration.

In certain embodiments, the handle feature 616 includes a gripping portion 642. In certain embodiments, the gripping portion 642 facilitates sliding of the latch component 600 by a user.

In certain embodiments, one or more fasteners 650 attach the latch component 600 to the riser bay. In certain embodiments, the one or more fasteners 650 are mounted within the travel channel 630. In certain embodiments, the one or more fasteners 650 move within the travel channel when the latch component moves between the locked configuration and the unlocked configuration.

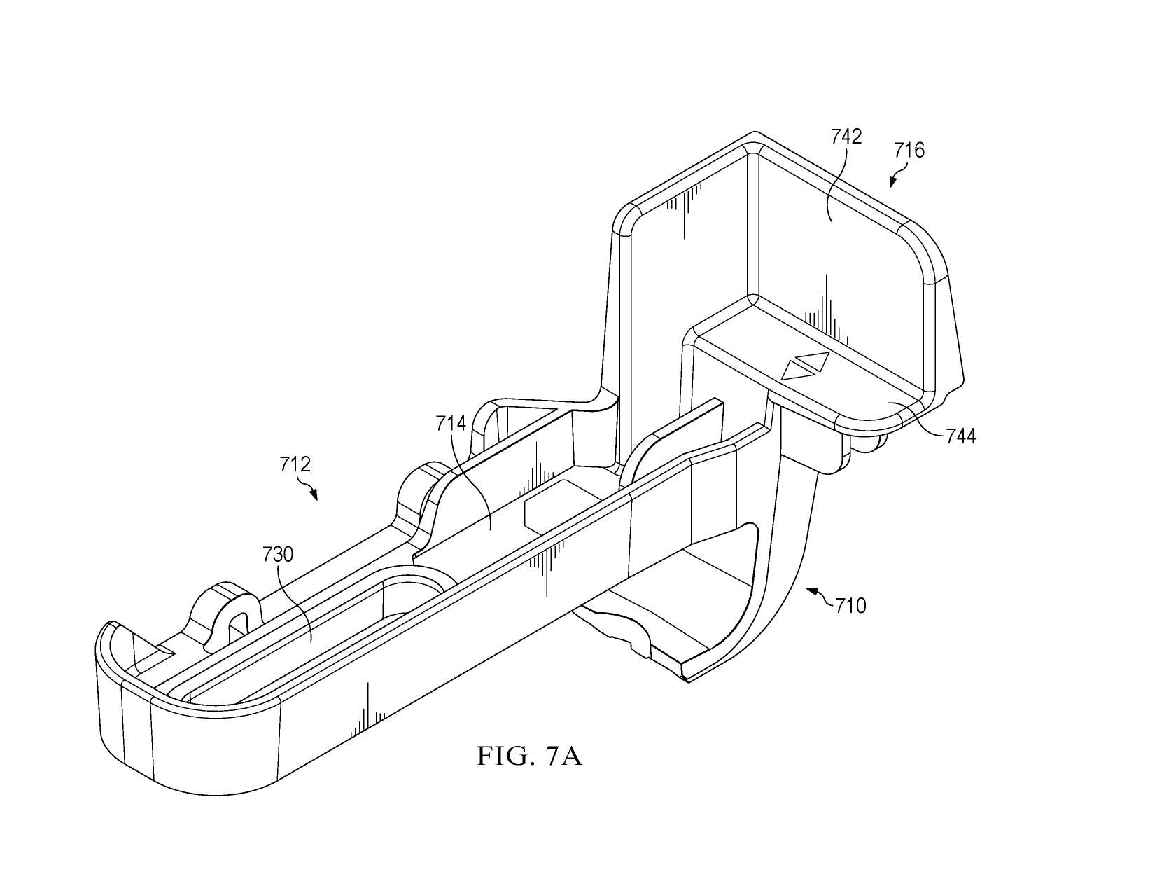

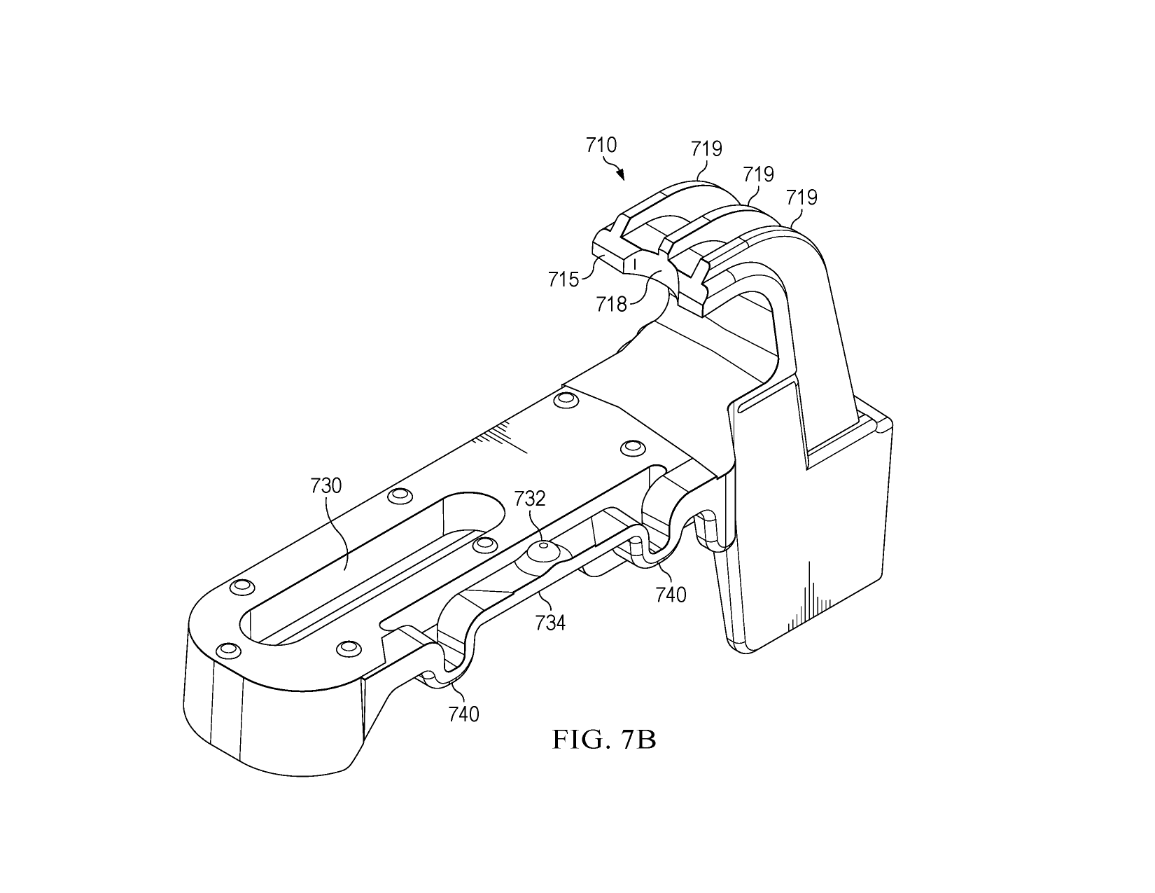

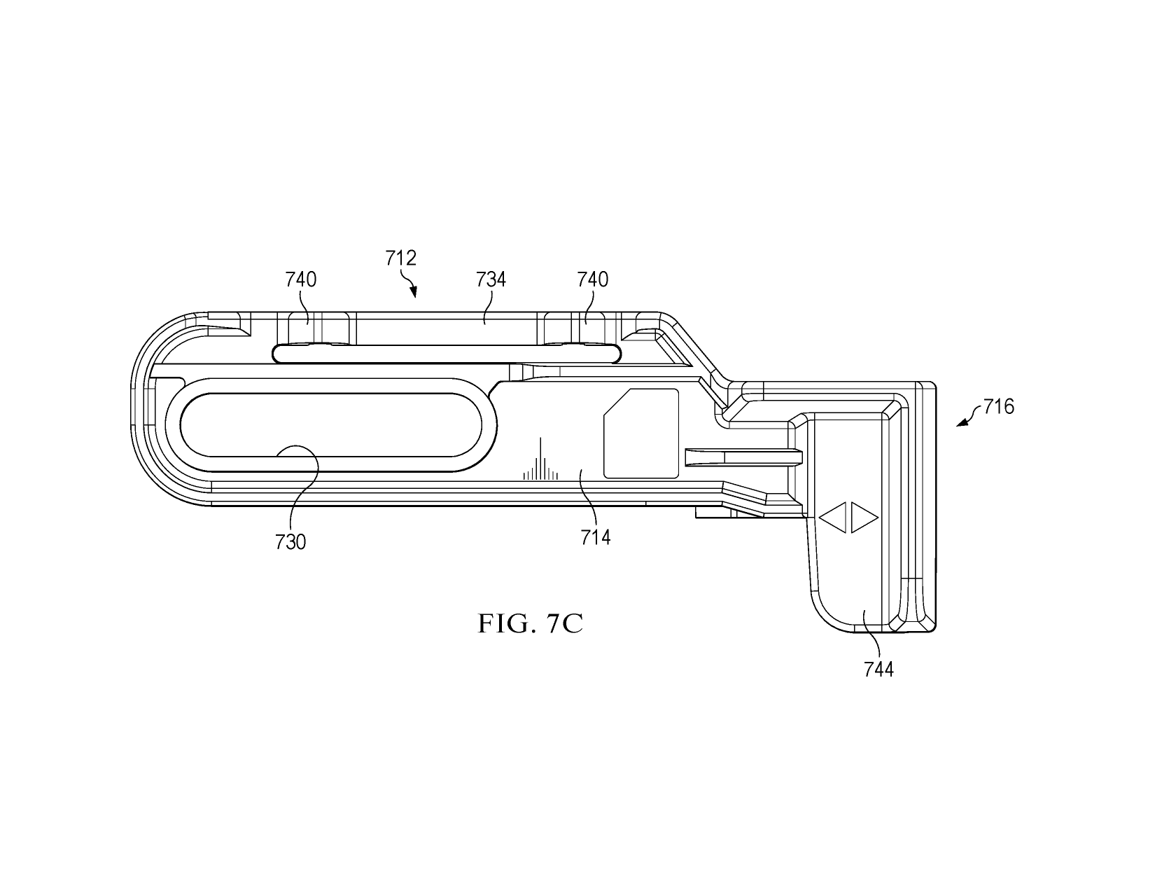

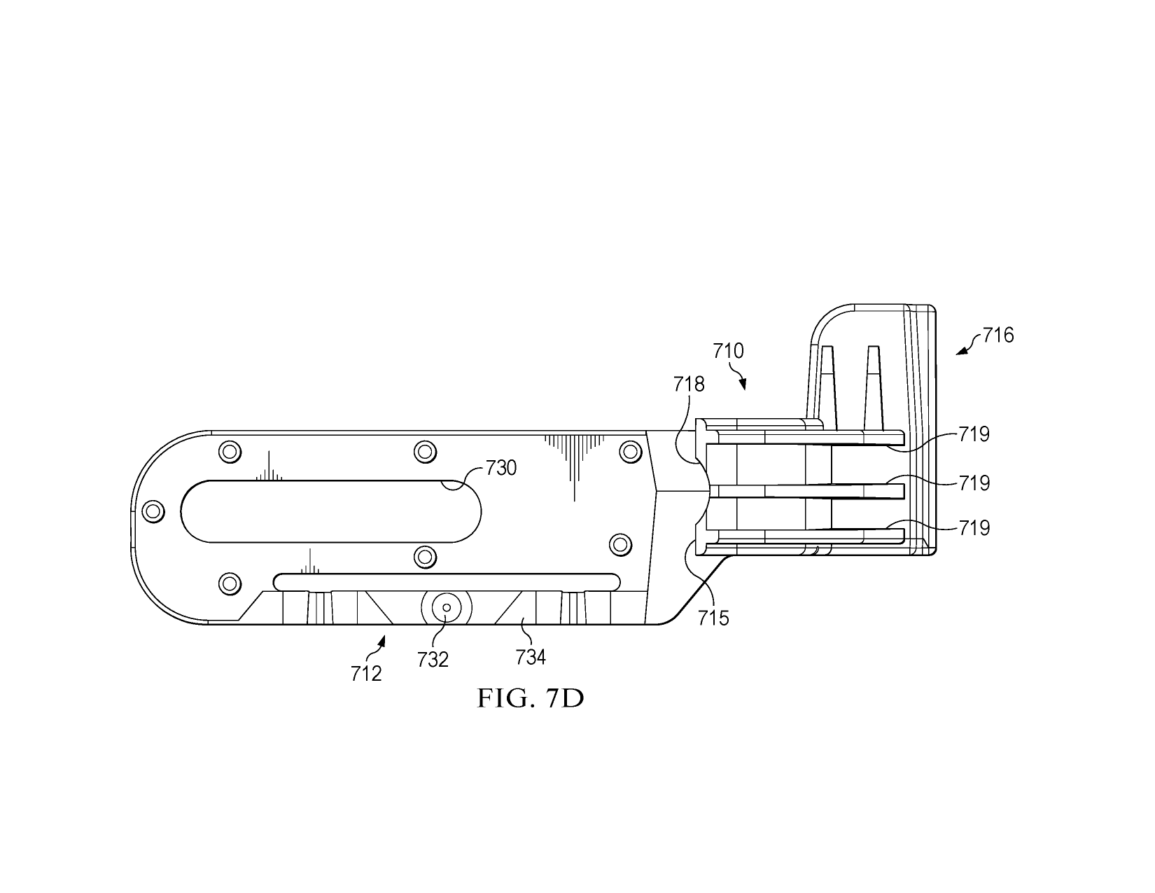

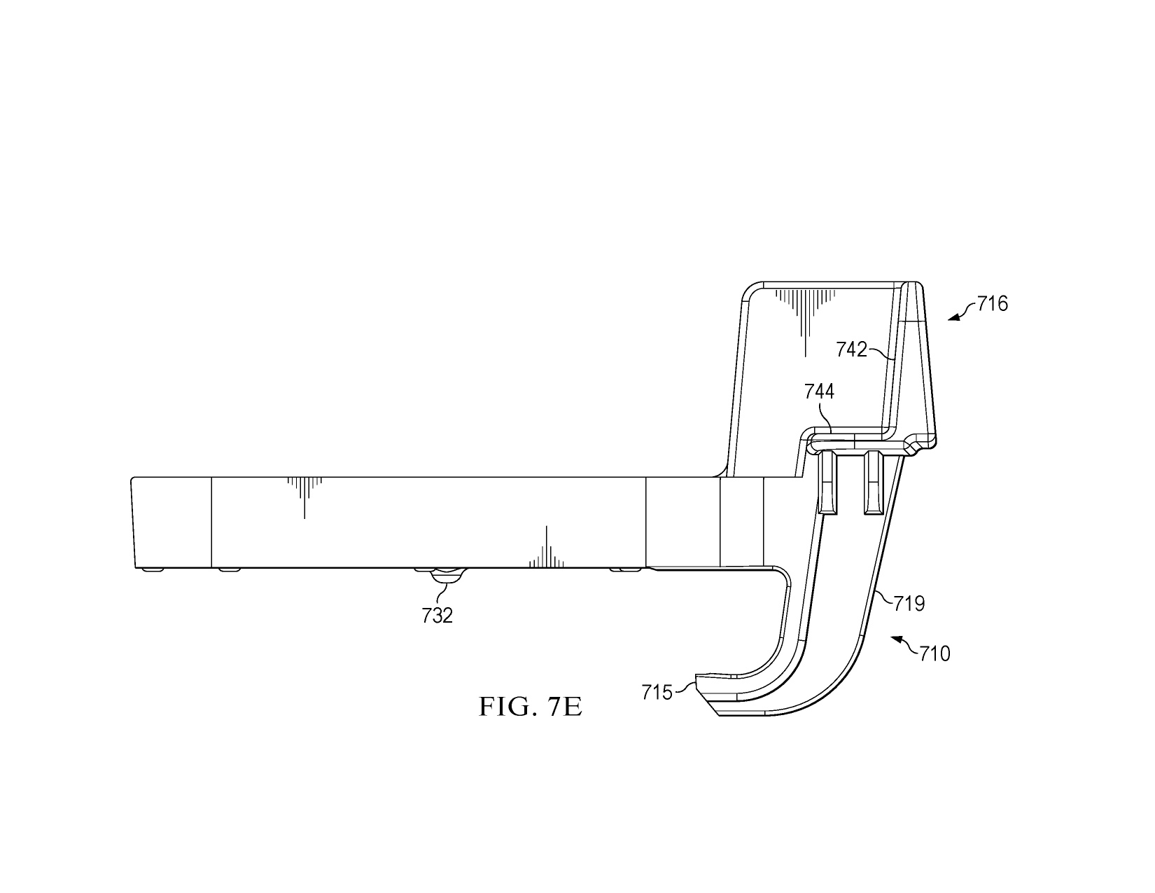

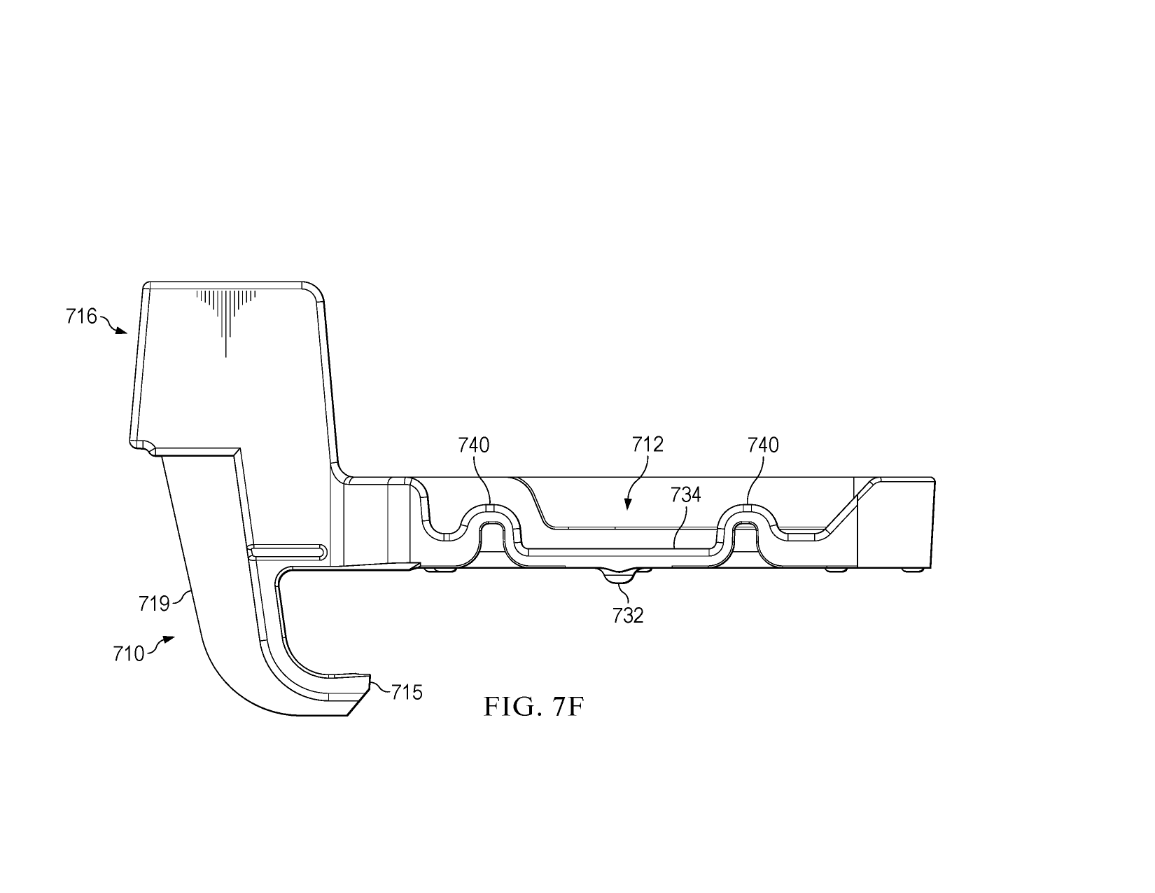

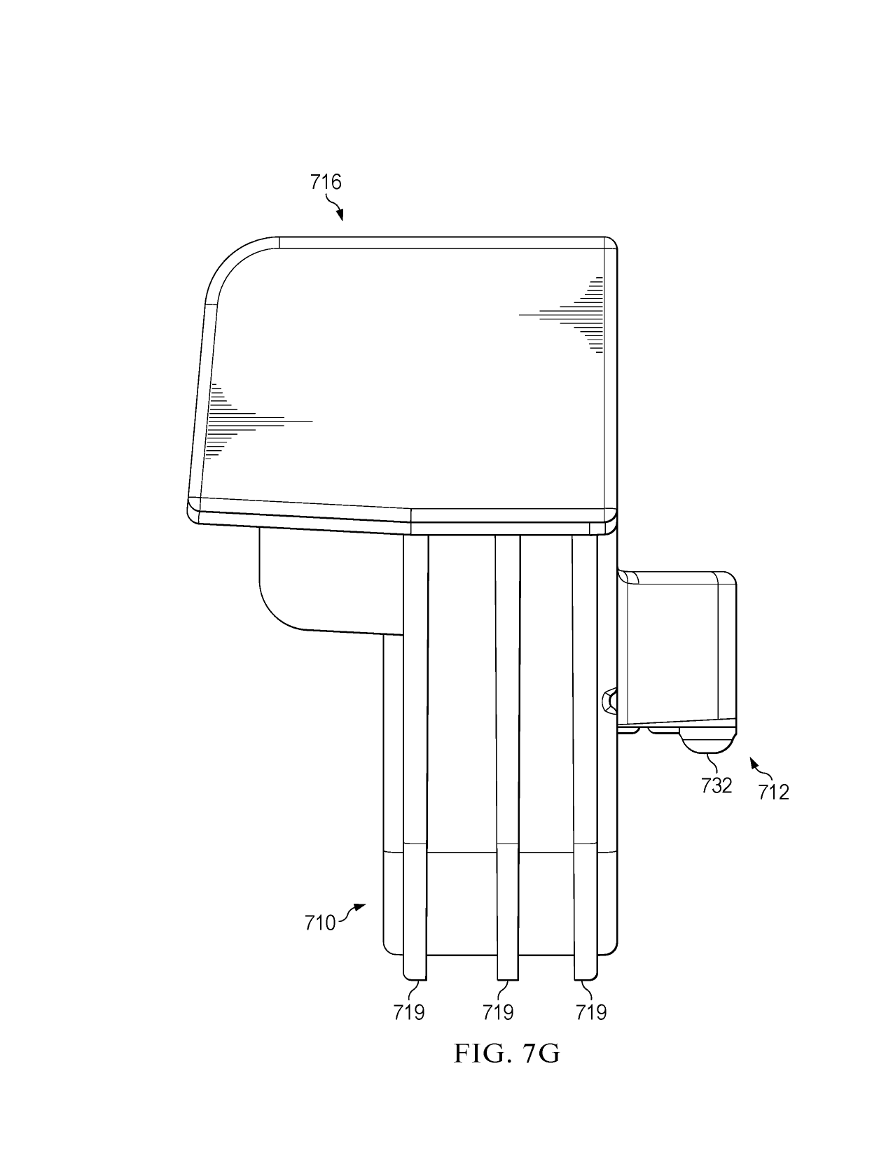

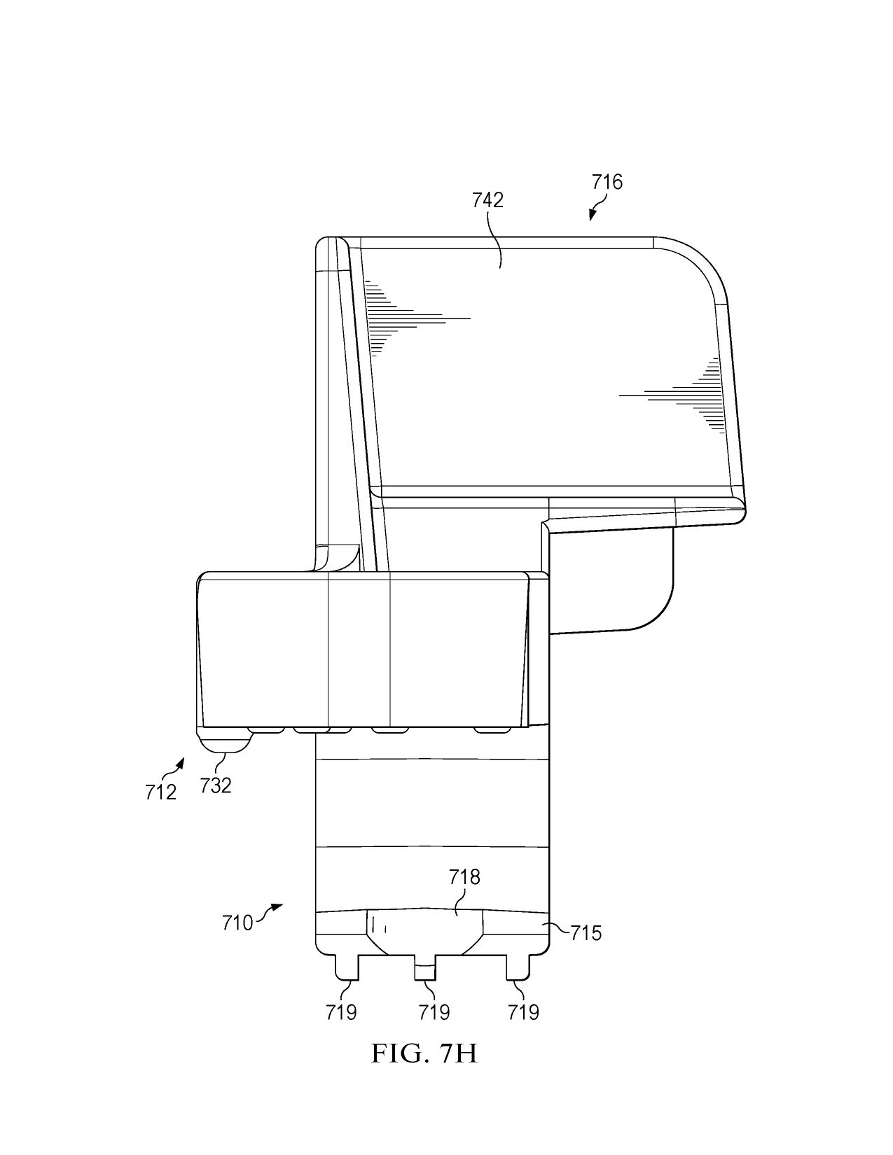

FIGS. 7A, 7B, 7C, 7D, 7E, 7F, 7G and 7H, generally referred to as FIG. 7, show a plurality of views of a latch component for a riser cage. More specifically, FIG. 7A shows a top perspective view of a latch component 700. FIG. 7B shows a bottom perspective view of a latch component 700. FIG. 7C shows a top view of a latch component 700. FIG. 7D shows a bottom view of a latch component 700. FIG. 7E shows a front view of a latch component 700. FIG. 7F shows a rear view of a latch component 700. FIG. 7G shows a right view of a latch component 700. FIG. 7H shows a left view of a latch component 700. In certain embodiments, the latch component 700 corresponds to latch component 410.

In certain embodiments, the latch component 700 includes a pin engagement feature 710, a travel control feature 712, a latch main housing portion 714, a handle feature 716, or a combination thereof. In certain embodiments, the pin engagement feature 710, the travel control feature 712, the handle feature 716, or a combination thereof, are physically coupled to the latch main housing portion. In certain embodiments, the pin engagement feature 710, the travel control feature 712, the latch main housing portion 714 and the handle feature 716 are constructed from a single piece of material. In certain embodiments, the pin engagement feature 710, the travel control feature 712, the latch main housing portion 714 and the handle feature 716 are constructed from plastic. In certain embodiments, the latch component 700 is constructed from a material having a color which is different from the color of the riser cage. In certain embodiments, by constructing the latch component 700 from a material having a color which is different from the color of the riser cage, the latch component 700 visually stands out when from the riser cage housing to which the latch component 700 is attached.

In certain embodiments, the pin engagement feature 710 interacts with the HPM. In certain embodiments, the pin engagement feature 710 interacts with a guide pin which is mounted to the HPM. In certain embodiments, when the latch component 700 is slid in one direction (e.g., towards the rear of the riser bay), the pin engagement feature 710 engages a guide pin. In certain embodiments, when the latch component 700 is slid in another direction (e.g., towards the front of the riser bay) the pin engagement feature 710 disengages the guide pin. In certain embodiments, the pin engagement feature 710 includes a hook structure 715. In certain embodiments, an end of the hook structure 712 defines a semicircular recess 718. In certain embodiments, the semicircular recess 718 mates with one side of the guide pin. In certain embodiments, the hook structure 712 includes one or more structural extensions 719. In certain embodiments, the one or more structural extensions 719 extend from an outside wall of the hook structure 718. In certain embodiments, the one or more structural extensions 719 increase the structural strength of the hook structure 715.

In certain embodiments, the travel control feature 720 includes a travel channel 730, a position fixing projection 732, an elastic arm 734, or a combination thereof. In certain embodiments, the travel channel 730 is shaped as an elongated oval with substantially straight inside edges. In certain embodiments, the position fixing projection 730 projects downwardly from the elastic arm 734. In certain embodiments, the position fixing projection 732 mates with a lock recess of a riser cage or an unlocked recess of a riser cage to hold the latch component in the locked configuration or the unlocked configuration, respectively. In certain embodiments, the elastic arm 734 includes one or more spring portions 740. In certain embodiments, the one or more spring portions 740 allow the elastic arm 734 to deflect when moving between a locked configuration and an unlocked configuration.

In certain embodiments, the handle feature 716 includes a gripping portion 742. In certain embodiments, the gripping portion 742 facilitates sliding of the latch component 700 by a user. In certain embodiments, the handle feature 716 includes arrow indicia 744 indicating the directions in which the latch component 700 can be moved.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A latch component of a peripheral mounting system for use with an information handling system, comprising:
a latch main housing portion;
a pin engagement feature physically coupled to the latch main housing portion; and,
a travel control feature physically coupled to the latch main housing, the travel control feature allowing the latch component to move in the peripheral mounting system between a locked position and an unlocked position.

2. The latch component of claim 1, further comprising:
a handle feature physically coupled to the latch main housing portion.

3. The latch component of claim 1, wherein:
the pin engagement feature interacts with a guide pin mounted within the information handling system.

4. The latch component of claim 3, wherein:
the pin engagement feature comprises a hook structure extending downwardly from the latch main housing portion, an end of the hook structure interacting with the guide pin when the latch component is in a locked position.

5. The latch component of claim 1, wherein:
the travel control feature includes position fixing projection, the position fixing projection mating with a lock recess defined by the peripheral mounting system when the latch component is in a locked position, the position fixing projection mating with an unlock recess defined by the peripheral mounting system when the latch component is in an unlocked position.

6. The latch component of claim 1, wherein:
the travel control feature includes a travel channel; and,
fasteners coupled to the peripheral mounting system move within the travel channel when the latch component moves in the peripheral mounting system between the locked position and the unlocked position.

7. A peripheral tray system for use with an information handling system comprising:
a chassis; and,
a peripheral mounting system mounted to the chassis, the peripheral mounting system comprising
a riser tray housing; and,
a latch component, the latch component comprising
a latch main housing portion;
a pin engagement feature physically coupled to the latch main housing portion; and,
a travel control feature physically coupled to the latch main housing, the travel control feature allowing the latch component to move in the peripheral mounting system between a locked position and an unlocked position.

8. The peripheral tray system of claim 7, wherein:
the latch component further comprise a handle feature physically coupled to the latch main housing portion.

9. The peripheral tray system of claim 7, wherein:
the pin engagement feature interacts with a guide pin mounted within the information handling system.

10. The peripheral tray system of claim 9, wherein:
the pin engagement feature comprises a hook structure extending downwardly from the latch main housing portion, an end of the hook structure interacting with the guide pin when the latch component is in a locked position.

11. The peripheral tray system of claim 7, wherein:
the travel control feature includes position fixing projection, the position fixing projection mating with a lock recess defined by the peripheral mounting system when the latch component is in a locked position, the position fixing projection mating with an unlock recess defined by the peripheral mounting system when the latch component is in an unlocked position.

12. The peripheral tray system of claim 11, wherein:
the travel control feature includes a travel channel; and,
fasteners coupled to the peripheral mounting system move within the travel channel when the latch component moves in the peripheral mounting system between the locked position and the unlocked position.

13. A system comprising:
a chassis;
a processor contained within the chassis;
a data bus coupled to the processor; and,
a peripheral mounting system comprising
a riser tray housing; and,
a latch component, the latch component comprising
a latch main housing portion;
a pin engagement feature physically coupled to the latch main housing portion; and,
a travel control feature physically coupled to the latch main housing, the travel control feature allowing the latch component to move in the peripheral mounting system between a locked position and an unlocked position.

14. The system of claim 13, wherein:
the latch component further comprise a handle feature physically coupled to the latch main housing portion.

15. The system of claim 13, wherein:
the pin engagement feature interacts with a guide pin mounted within the information handling system.

16. The system of claim 15, wherein:
the pin engagement feature comprises a hook structure extending downwardly from the latch main housing portion, an end of the hook structure interacting with the guide pin when the latch component is in a locked position.

17. The system of claim 13, wherein:
the travel control feature includes position fixing projection, the position fixing projection mating with a lock recess defined by the peripheral mounting system when the latch component is in a locked position, the position fixing projection mating with an unlock recess defined by the peripheral mounting system when the latch component is in an unlocked position.

18. The system of claim 13, wherein:
the travel control feature includes a travel channel; and,
fasteners coupled to the peripheral mounting system move within the travel channel when the latch component moves in the peripheral mounting system between the locked position and the unlocked position.
